(19) United States
(12) Patent Application Publication
(10) Pub. No.: US 2018/0219184 A1
(43) Pub. Date: Aug. 2, 2018

(54) MANUFACTURING METHOD OF AMOLED PIXEL DRIVER CIRCUIT

(71) Applicant: SHENZHEN CHINA STAR OPTOELECTRONICS TECHNOLOGY CO., LTD., Shenzhen City (CN)

(72) Inventors: Shipeng Chi, Shenzhen City (CN); Yuanchun Wu, Shenzhen City (CN)

(73) Assignee: SHENZHEN CHINA STAR OPTOELECTRONICS TECHNOLOGY CO., LTD., Shenzhen City (CN)

(21) Appl. No.: 15/328,498

(22) PCT Filed: Dec. 19, 2016
(86) PCT No.: PCT/CN2016/110727

§ 371 Date: Jan. 24, 2017

(30) Foreign Application Priority Data
Sep. 18, 2016 (CN) 201610828093.6

(51) Int. Cl. H01L 51/56; H01L 27/32; H01L 51/52; H01L 51/00

(52) U.S. Cl. CPC H01L 51/56; H01L 27/3262; H01L 2227/323; H01L 51/5206; H01L 51/0005; H01L 51/5221

(57) ABSTRACT

The invention provides a manufacturing method of AMOLED pixel driver circuit, by leaving only a second insulation layer (5) covering the second active area (42) as an etch-stopping layer, making an ES-type driving TFT (T2), and a BCE-type switching TFT (T1). BCE-type switching TFT (T1) has a smaller parasitic capacitance, can reduce the RC effect, and is good for controlling the alternating data signal; ES-type driving TFT (T2) has excellent device characteristics, and can provide a stable OLED current to ensure the stability and uniformity of OLED light-emission.

### BACKGROUND OF THE INVENTION

### 1. Field of the Invention

The present invention relates to the field of display techniques, and in particular to a manufacturing method of AMOLED pixel driver and thereof.

### 2. The Related Arts

The organic light emitting diode (OLED) display provides the advantages of active light-emitting, low driving voltage, high emission efficiency, quick response time, high resolution and contrast, near 180° viewing angle, wide operation temperature range, and capability to realize flexible display and large-area full-color display, and is regarded as the most promising display technology.

The driving types of OLED can be divided, according to the driving method, into the passive matrix OLED (PMOLED) and active matrix OLED (AMOLED), i.e., the direct addressable type and thin film transistor (TFT) addressable type, wherein the AMOLED provides the advantages of pixels arranged in an array, self-luminous, and high luminous efficiency and is commonly used for high definition large-size display.

AMOLED is a current-driven device that requires using active drive to provide current to OLED to achieve appropriate light-emitting luminance, wherein the active drive is realized by pixel driver circuit formed by thin film transistors (TFT) and capacitors. Take the common 2T1C pixel driver circuit as example. The TFTs are divided into a driving TFT and a switching TFT, wherein the driving TFT is for providing current to the OLED and the switching TFT is for controlling the data registration signals.

The TFTs of the pixel driver circuit can be realized through different structures and processes, such as, the bottom-gate interleaved structure can be fabricated using Etch Stopper (ES) and Back Channel Etching (BCE) processes to fabricate. At present, ES-type TFT process is more mature, and good device performance can be obtained. However, ES-structure leads to large parasitic capacitance of TFT. When used as switching TFT, large resistance-capacitance (RC) resulting in delay of alternating signals and affecting the response speed of the circuit. Compared with the ES-type TFT, the BCE-type TFT has a smaller parasitic capacitance, which can reduce the influence of the RC. However, the BCE process causes other problems, and results in poor TFT characteristics.

In the AMOLED pixel drive circuit, the use of ES-type TFT will produce a larger parasitic capacitance and increase the RC effect of data signal; on the other hand, although the use of BCE-type TFT can effectively reduce the parasitic capacitance, the TFTs from the BCE process perform less well than the ES-type TFTs, which will have a negative impact on the light-emission of OLED.

### SUMMARY OF THE INVENTION

The object of the present invention is to provide an AMOLED pixel driver circuit, able to fabricate ES-type TFT and BCE-type TFT at the same time, with the ES-type TFT used as driving TFT and BCE-type TFT used as switching TFT so as to reduce RC effect and facilitate controlling the alternating data signal, as well as to provide stable current to the OLED to ensure light-emission stability and uniformity of the OLED.

To achieve the above object, the present invention provides a manufacturing method of AMOLED driver circuit, which comprises:

Step 1: providing a base substrate, depositing and etching a first metal layer on the base substrate to form a patternized first gate and a second gate;

Step 2: depositing a gate insulation layer to cover the base substrate, the first gate and the second gate;

Step 3: depositing and etching a semiconductor layer on the gate insulation layer to form a patternized first active area and a second active area above the first gate and the second gate respectively;

Step 4: depositing and etching a second insulation layer on the first active area, the second active area and the gate insulation layer and leaving the second insulation layer covering the second active area as an etch-stopping layer, and etching a first contact via, a second contact via on the etch-stopping layer to expose the two sides of the second active area;

Step 5: etching the gate insulation layer to form a third contact via to expose a side of the second gate close to the first gate;

Step 6: depositing and etching a second metal layer on the first active area, the etch-stopping layer and the gate insulation layer to form a patternized first source, a first drain, a second source, and a second drain; the first source directly contacting the side of the first active area close to the second active area and connecting to the second gate through the third contact via, the first drain directly contacting the other side of the first active area; the second source and the second drain contacting the two sides of the second active area through the first contact via and the second contact via respectively;

the first source, the first drain, the first active area, the gate insulation layer and the first gate forming a switching TFT; and the second source, the second drain, the etch-stopping layer, the second active area, the gate insulation layer and the second gate forming a driving TFT.

According to a preferred embodiment of the present invention, the manufacturing method of AMOLED pixel driver circuit further comprises:

Step 7: depositing a passivation protection layer and a first organic planarization layer in sequence, and then etching to form a fourth contact via penetrating through the passivation protection layer and the first organic planarization layer to expose a portion of surface of the second source;

Step 8: depositing and etching a transparent conductive layer on the first organic planarization layer to form an OLED anode, the OLED anode connecting to the second source through the fourth contact via;

Step 9: depositing and etching a second organic planarization layer on the OLED anode and the first organic planarization layer to form a fifth contact via exposing a portion of surface of the OLED anode;

Step 10: preparing an OLED light-emitting layer inside the fifth contact via;

Step 11: depositing an OLED cathode covering the OLED light-emitting layer and the second organic flat layer;

Step 12: packaging.

According to a preferred embodiment of the present invention, the base substrate is a glass substrate.

According to a preferred embodiment of the present invention, the material for the gate insulation layer and the etch-stopping layer is silicon oxide, silicon nitride, or a combination of the two.

According to a preferred embodiment of the present invention, the material of the semiconductor layer is a metal oxide semiconductor, or an amorphous silicon semiconductor (a-Si).

According to a preferred embodiment of the present invention, the material of the semiconductor layer is indium gallium zinc oxide.

According to a preferred embodiment of the present invention, the material of the first metal layer and the second metal layer is a stack combination of one or more of molybdenum (Mo), titanium (Ti), aluminum (Al), copper (Cu) and silver (Ag).

According to a preferred embodiment of the present invention, the material of the passivation protection layer is silicon oxide, silicon nitride, or a combination of the two.

According to a preferred embodiment of the present invention, the material of the transparent conductive layer is indium tin oxide (ITO).

According to a preferred embodiment of the present invention, Step 10 uses an evaporation process or an ink-jet printing process to prepare an OLED light-emitting layer;

and Step 11 uses an evaporation process to deposit an overlaying OLED cathode.

Another embodiment of the present invention provides a manufacturing method of AMOLED pixel driver circuit, which comprises:

Step 1: providing a base substrate, depositing and etching a first metal layer on the base substrate to form a patternized first gate and a second gate;

Step 2: depositing a gate insulation layer to cover the base substrate, the first gate and the second gate;

Step 3: depositing and etching a semiconductor layer on the gate insulation layer to form a patternized first active area and a second active area above the first gate and the second gate respectively;

Step 4: depositing and etching a second insulation layer on the first active area, the second active area and the gate insulation layer and leaving the second insulation layer covering the second active area as an etch-stopping layer, and etching a first contact via, a second contact via on the etch-stopping layer to expose the two sides of the second active area;

Step 5: etching the gate insulation layer to form a third contact via to expose a side of the second gate close to the first gate;

Step 6: depositing and etching a second metal layer on the first active area, the etch-stopping layer and the gate insulation layer to form a patternized first source, a first drain, a second source, and a second drain; the first source directly contacting the side of the first active area close to the second active area and connecting to the second gate through the third contact via, the first drain directly contacting the other side of the first active area; the second source and the second drain contacting the two sides of the second active area through the first contact via and the second contact via respectively;

the first source, the first drain, the first active area, the gate insulation layer and the first gate forming a switching TFT; and the second source, the second drain, the etch-stopping layer, the second active area, the gate insulation layer and the second gate forming a driving TFT;

Step 7: depositing a passivation protection layer and a first organic planarization layer in sequence, and then etching to form a fourth contact via penetrating through the passivation protection layer and the first organic planarization layer to expose a portion of surface of the second source;

Step 8: depositing and etching a transparent conductive layer on the first organic planarization layer to form an OLED anode, the OLED anode connecting to the second source through the fourth contact via;

Step 9: depositing and etching a second organic planarization layer on the OLED anode and the first organic planarization layer to form a fifth contact via exposing a portion of surface of the OLED anode;

Step 10: preparing an OLED light-emitting layer inside the fifth contact via;

Step 11: depositing an OLED cathode covering the OLED light-emitting layer and the second organic flat layer;

Step 12: packaging;

wherein the base substrate being a glass substrate.

Compared to the known techniques, the present invention provides the following advantages. The present invention provides a manufacturing method of AMOLED pixel driver circuit, by leaving only a second insulation layer covering the second active area as an etch-stopping layer, making an ES-type driving TFT, and a BCE-type switching TFT. BCE-type switching TFT has a smaller parasitic capacitance, can reduce the RC effect, and is good for controlling the alternating data signal; ES-type driving TFT has excellent device characteristics, and can provide a stable OLED current to ensure the stability and uniformity of OLED light-emission.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the flowchart of the manufacturing method of AMOLED pixel driver circuit provided by an embodiment of the present invention;

FIG. 2 is a schematic view showing Step 1 of the manufacturing method of AMOLED pixel driver circuit provided by an embodiment of the present invention;

FIG. 3 is a schematic view showing Step 2 of the manufacturing method of AMOLED pixel driver circuit provided by an embodiment of the present invention;

FIG. 4 is a schematic view showing Step 3 of the manufacturing method of AMOLED pixel driver circuit provided by an embodiment of the present invention;

FIG. 5 is a schematic view showing Step 4 of the manufacturing method of AMOLED pixel driver circuit provided by an embodiment of the present invention;

FIG. 6 is a schematic view showing Step 5 of the manufacturing method of AMOLED pixel driver circuit provided by an embodiment of the present invention;

FIG. 7 is a schematic view showing Step 6 of the manufacturing method of AMOLED pixel driver circuit provided by an embodiment of the present invention;

FIG. 8 is a schematic view showing Step 7 of the manufacturing method of AMOLED pixel driver circuit provided by an embodiment of the present invention;

FIG. 9 is a schematic view showing Step 8 of the manufacturing method of AMOLED pixel driver circuit provided by an embodiment of the present invention;

FIG. 10 is a schematic view showing Step 9 of the manufacturing method of AMOLED pixel driver circuit provided by ant embodiment of the present invention;

FIG. 11 is a schematic view showing Step 10 of the manufacturing method of AMOLED pixel driver circuit provided by an embodiment of the present invention;

FIG. 12 is a schematic view showing Step 11 of the manufacturing method of AMOLED pixel driver circuit provided by an embodiment of the present invention.

### DETAILED DESCRIPTION OF THE PREFERRED EMBODIMENTS

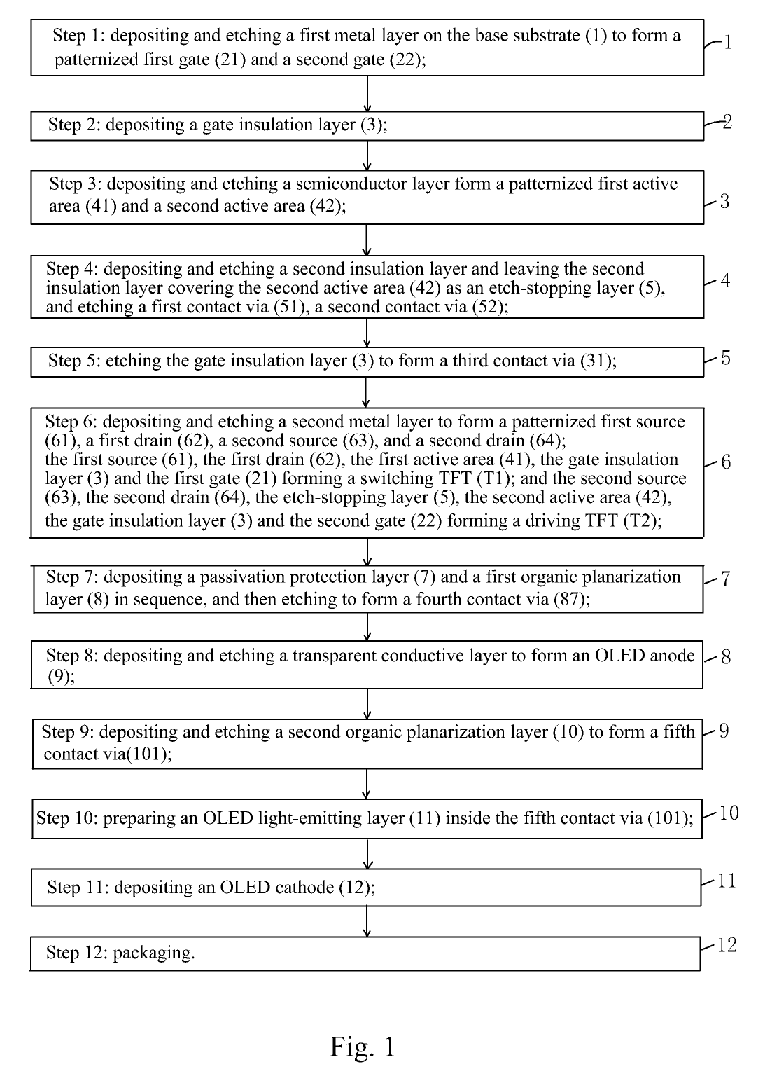

Referring to FIG. 1, the present invention provides a manufacturing method of AMOLED pixel driver circuit, which comprises the following steps:

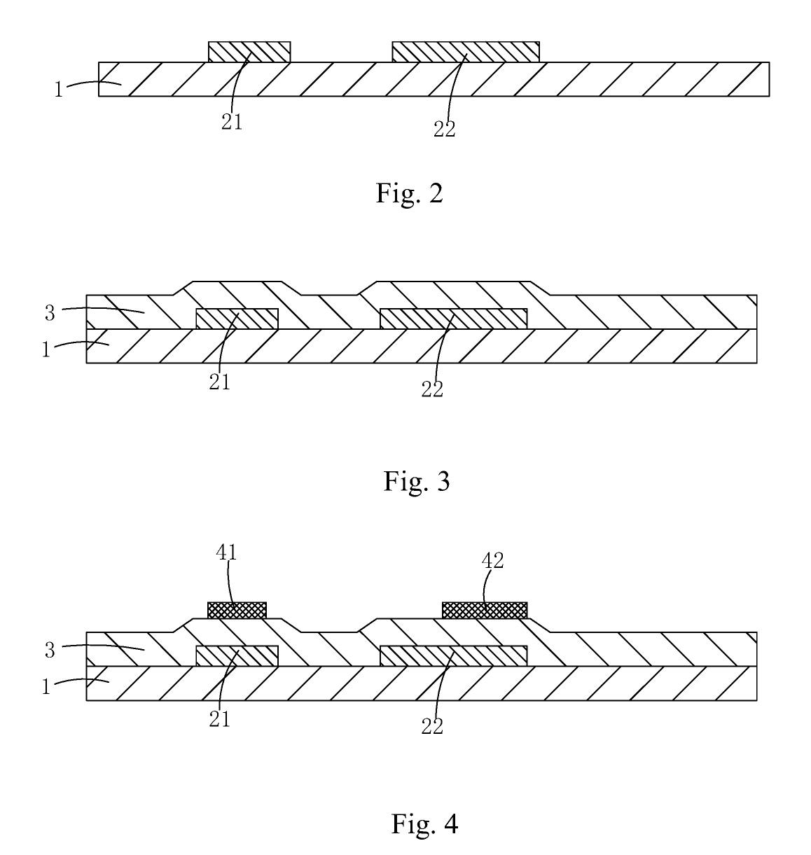

Step 1: as shown in FIG. 2, providing a base substrate 1, depositing and etching a first metal layer on the base substrate 1 to form a patternized first gate 21 and a second gate 22.

Specifically, the substrate is a transparent substrate, and preferably, a glass substrate.

The material of the first metal layer is a stack combination of one or more of molybdenum (Mo), titanium (Ti), aluminum (Al), copper (Cu) and silver (Ag).

Step 2: as shown in FIG. 3, depositing a gate insulation layer 3 to cover the base substrate 1, the first gate 21 and the second gate 22.

Specifically, the material for the gate insulation layer is silicon oxide (SiOx), silicon nitride (SiNx), or a combination of the two.

Step 3: as shown in FIG. 4, depositing and etching a semiconductor layer on the gate insulation layer 3 to form a patternized first active area 41 and a second active area 42 above the first gate 21 and the second gate 22 respectively.

Specifically, the material of the semiconductor layer can be, but not limited to, a metal oxide semiconductor, or an amorphous silicon semiconductor (a-Si); and preferably, the material of the semiconductor layer is indium gallium zinc oxide (IGZO).

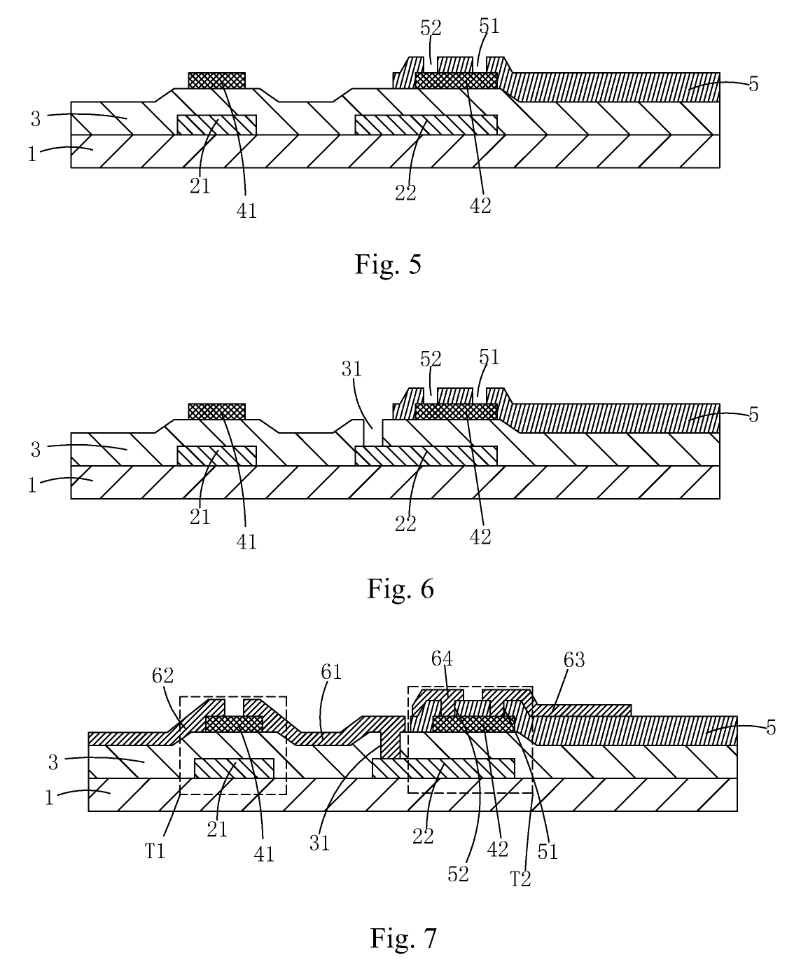

Step 4: as shown in FIG. 5, depositing and etching a second insulation layer on the first active area 41, the second active area 42 and the gate insulation layer 3 and leaving the second insulation layer covering the second active area 42 as an etch-stopping layer 5, and etching a first contact via 51, a second contact via 52 on the etch-stopping layer 5 to expose the two sides of the second active area 42.

Specifically, the material for the etch-stopping layer is silicon oxide, silicon nitride, or a combination of the two.

Step 5: as shown in FIG. 6, etching the gate insulation layer 3 to form a third contact via 31 to expose a side of the second gate 22 close to the first gate 21.

Step 6: as shown in FIG. 7, depositing and etching a second metal layer on the first active area 41, the etch-stopping layer 5 and the gate insulation layer 3 to form a patternized first source 61, a first drain 62, a second source 63, and a second drain 64; the first source 61 directly contacting the side of the first active area 41 close to the second active area 42 and connecting to the second gate 22 through the third contact via 31, the first drain 62 directly contacting the other side of the first active area 41; the second source 63 and the second drain 64 contacting the two sides of the second active area 42 through the first contact via 51 and the second contact via 52 respectively.

The first source 61, the first drain 62, the first active area 41, the gate insulation layer 3 and the first gate 21 form the switching TFT T1. Because the first source 61 and the first drain 62 contact directly with the first active area 41 without the etch-stopping layer 5 in-between, the switching TFT T1 is a BCE-type TFT. The second source 63, the second drain 64, the etch-stopping layer 5, the second active area 42, the gate insulation layer 3 and the second gate 22 form the driving TFT T2. Because the second source 63 and the second drain 64 are separated from the second active area 42 by the etch-stopping layer 5, the driving TFT T2 is an ES-type TFT.

For the AMOLED pixel driver circuit, the BCE-type switching TFT T1 has a smaller parasitic capacitance, can reduce the RC effect, and is good for controlling the alternating data signal; the ES-type driving TFT T2 has excellent device characteristics, and can provide a stable OLED current to ensure the stability and uniformity of OLED light-emission.

Specifically, the material of the second metal layer in Step 6 is a stack combination of one or more of molybdenum (Mo), titanium (Ti), aluminum (Al), copper (Cu) and silver (Ag).

Furthermore, the manufacturing method of AMOLED pixel driver circuit further comprises:

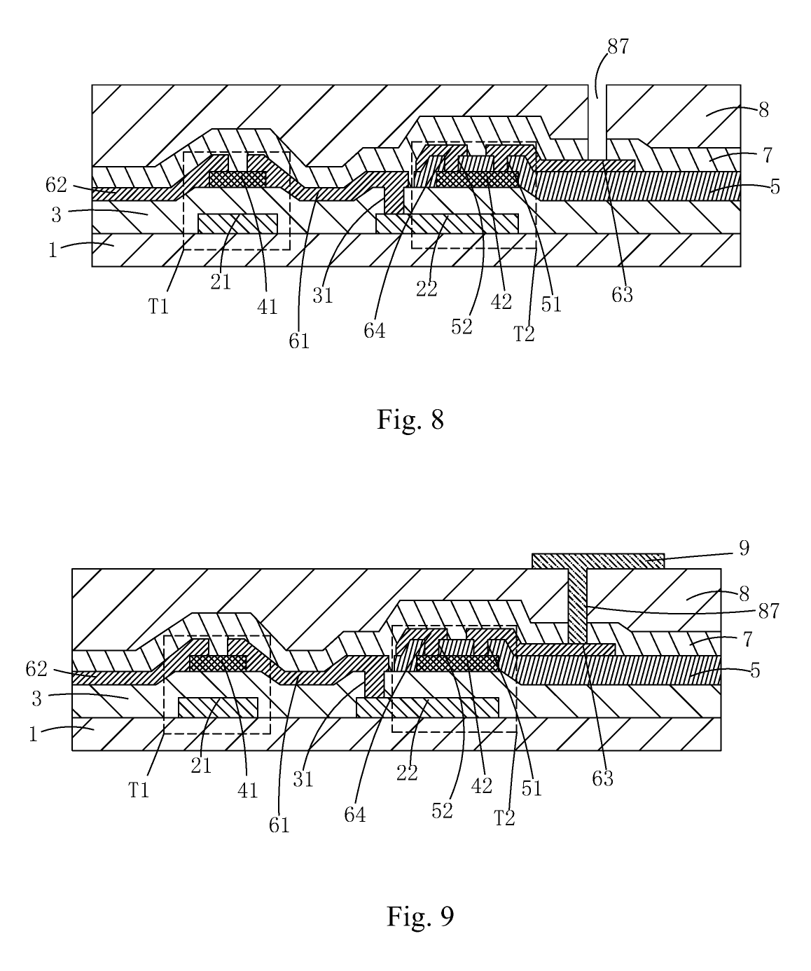

Step 7: as shown in FIG. 8, depositing a passivation protection layer 7 and a first organic planarization layer 8 in sequence, and then etching to form a fourth contact via 87 penetrating through the passivation protection layer 7 and the first organic planarization layer 8 to expose a portion of surface of the second source 63.

Specifically, the material of the passivation protection layer 7 is silicon oxide, silicon nitride, or a combination of the two.

Step 8: as shown in FIG. 9, depositing and etching a transparent conductive layer on the first organic planarization layer 8 to form an OLED anode 9, the OLED anode 9 connecting to the second source 63 through the fourth contact via 87.

Specifically, the material of the transparent conductive layer is indium tin oxide (ITO).

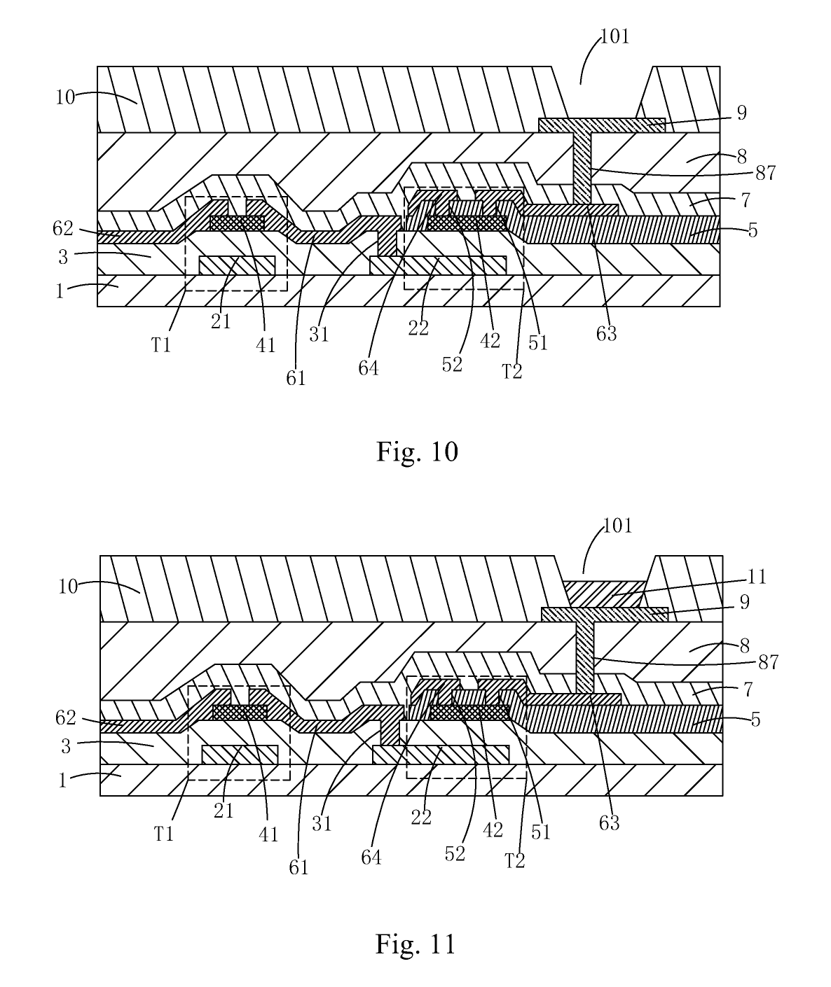

Step 9: as shown in FIG. 10, depositing and etching a second organic planarization layer 10 on the OLED anode 9 and the first organic planarization layer 8 to form a fifth contact via 101 exposing a portion of surface of the OLED anode 9.

Step 10: as shown in FIG. 11, preparing an OLED light-emitting layer 11 inside the fifth contact via 101.

Specifically, Step 10 uses an evaporation process or an ink-jet printing (IJP) process to prepare an OLED light-emitting layer 11.

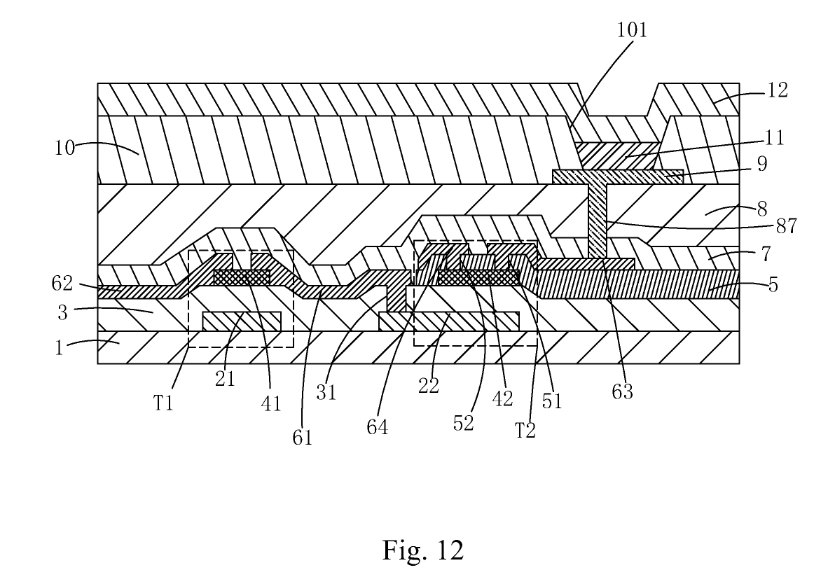

Step 11: as shown in FIG. 12, depositing an OLED cathode 12 covering the OLED light-emitting layer 11 and the second organic flat layer 10.

Specifically, Step 11 uses an evaporation process to deposit an overlaying OLED cathode 12.

Step 12: packaging.

At this point, the manufacturing of the AMOLED pixel driver circuit is complete.

In summary, the present invention provides a manufacturing method of AMOLED pixel driver circuit, by leaving only a second insulation layer covering the second active area as an etch-stopping layer, making an ES-type driving TFT, and a BCE-type switching TFT. BCE-type switching TFT has a smaller parasitic capacitance, can reduce the RC effect, and is good for controlling the alternating data signal; ES-type driving TFT has excellent device characteristics, and can provide a stable OLED current to ensure the stability and uniformity of OLED light-emission.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

What is claimed is:

1. A manufacturing method of AMOLED driver circuit, which comprises:
Step 1: providing a base substrate, depositing and etching a first metal layer on the base substrate to form a patternized first gate and a second gate;
Step 2: depositing a gate insulation layer to cover the base substrate, the first gate and the second gate;
Step 3: depositing and etching a semiconductor layer on the gate insulation layer to form a patternized first active area and a second active area above the first gate and the second gate respectively;
Step 4: depositing and etching a second insulation layer on the first active area, the second active area and the gate insulation layer and leaving the second insulation layer covering the second active area as an etch-stopping layer, and etching a first contact via, a second contact via on the etch-stopping layer to expose the two sides of the second active area;
Step 5: etching the gate insulation layer to form a third contact via to expose a side of the second gate close to the first gate;
Step 6: depositing and etching a second metal layer on the first active area, the etch-stopping layer and the gate insulation layer to form a patternized first source, a first drain, a second source, and a second drain; the first source directly contacting the side of the first active area close to the second active area and connecting to the second gate through the third contact via, the first drain directly contacting the other side of the first active area; the second source and the second drain contacting the two sides of the second active area through the first contact via and the second contact via respectively;
the first source, the first drain, the first active area, the gate insulation layer and the first gate forming a switching TFT; and the second source, the second drain, the etch-stopping layer, the second active area, the gate insulation layer and the second gate forming a driving TFT.

2. The manufacturing method of AMOLED driver circuit as claimed in claim 1, wherein the manufacturing method of AMOLED pixel driver circuit further comprises:
Step 7: depositing a passivation protection layer and a first organic planarization layer in sequence, and then etching to form a fourth contact via penetrating through the passivation protection layer and the first organic planarization layer to expose a portion of surface of the second source;
Step 8: depositing and etching a transparent conductive layer on the first organic planarization layer to form an OLED anode, the OLED anode connecting to the second source through the fourth contact via;
Step 9: depositing and etching a second organic planarization layer on the OLED anode and the first organic planarization layer to form a fifth contact via exposing a portion of surface of the OLED anode;
Step 10: preparing an OLED light-emitting layer inside the fifth contact via;
Step 11: depositing an OLED cathode covering the OLED light-emitting layer and the second organic flat layer;
Step 12: packaging.

3. The manufacturing method of AMOLED driver circuit as claimed in claim 1, wherein the base substrate is a glass substrate.

4. The manufacturing method of AMOLED driver circuit as claimed in claim 1, wherein the material for the gate insulation layer and the etch-stopping layer is silicon oxide, silicon nitride, or a combination of the two.

5. The manufacturing method of AMOLED driver circuit as claimed in claim 1, wherein the material of the semiconductor layer is a metal oxide semiconductor, or an amorphous silicon semiconductor (a-Si).

6. The manufacturing method of AMOLED driver circuit as claimed in claim 5, wherein the material of the semiconductor layer is indium gallium zinc oxide.

7. The manufacturing method of AMOLED driver circuit as claimed in claim 1, wherein the material of the first metal layer and the second metal layer is a stack combination of one or more of molybdenum (Mo), titanium (Ti), aluminum (Al), copper (Cu) and silver (Ag).

8. The manufacturing method of AMOLED driver circuit as claimed in claim 2, wherein the material of the passivation protection layer is silicon oxide, silicon nitride, or a combination of the two.

9. The manufacturing method of AMOLED driver circuit as claimed in claim 2, wherein the material of the transparent conductive layer is indium tin oxide (ITO).

10. The manufacturing method of AMOLED driver circuit as claimed in claim 2, wherein Step 10 uses an evaporation process or an ink-jet printing process to prepare an OLED light-emitting layer; and Step 11 uses an evaporation process to deposit an overlaying OLED cathode.

11. A manufacturing method of AMOLED driver circuit, which comprises:
Step 1: providing a base substrate, depositing and etching a first metal layer on the base substrate to form a patternized first gate and a second gate;
Step 2: depositing a gate insulation layer to cover the base substrate, the first gate and the second gate;
Step 3: depositing and etching a semiconductor layer on the gate insulation layer to form a patternized first active area and a second active area above the first gate and the second gate respectively;
Step 4: depositing and etching a second insulation layer on the first active area, the second active area and the gate insulation layer and leaving the second insulation layer covering the second active area as an etch-stopping layer, and etching a first contact via, a second contact via on the etch-stopping layer to expose the two sides of the second active area;
Step 5: etching the gate insulation layer to form a third contact via to expose a side of the second gate close to the first gate;
Step 6: depositing and etching a second metal layer on the first active area, the etch-stopping layer and the gate insulation layer to form a patternized first source, a first drain, a second source, and a second drain; the first source directly contacting the side of the first active area close to the second active area and connecting to the second gate through the third contact via, the first drain directly contacting the other side of the first active area; the second source and the second drain contacting the two sides of the second active area through the first contact via and the second contact via respectively;
the first source, the first drain, the first active area, the gate insulation layer and the first gate forming a switching TFT; and the second source, the second drain, the etch-stopping layer, the second active area, the gate insulation layer and the second gate forming a driving TFT.
Step 7: depositing a passivation protection layer and a first organic planarization layer in sequence, and then etching to form a fourth contact via penetrating through the passivation protection layer and the first organic planarization layer to expose a portion of surface of the second source;
Step 8: depositing and etching a transparent conductive layer on the first organic planarization layer to form an OLED anode, the OLED anode connecting to the second source through the fourth contact via;
Step 9: depositing and etching a second organic planarization layer on the OLED anode and the first organic planarization layer to form a fifth contact via exposing a portion of surface of the OLED anode;
Step 10: preparing an OLED light-emitting layer inside the fifth contact via;
Step 11: depositing an OLED cathode covering the OLED light-emitting layer and the second organic flat layer;
Step 12: packaging;
wherein the base substrate being a glass substrate.

12. The manufacturing method of AMOLED driver circuit as claimed in claim 11, wherein the material for the gate insulation layer and the etch-stopping layer is silicon oxide, silicon nitride, or a combination of the two.

13. The manufacturing method of AMOLED driver circuit as claimed in claim 11, wherein the material of the semiconductor layer is a metal oxide semiconductor, or an amorphous silicon semiconductor (a-Si).

14. The manufacturing method of AMOLED driver circuit as claimed in claim 13, wherein the material of the semiconductor layer is indium gallium zinc oxide.

15. The manufacturing method of AMOLED driver circuit as claimed in claim 11, wherein the material of the first metal layer and the second metal layer is a stack combination of one or more of molybdenum (Mo), titanium (Ti), aluminum (Al), copper (Cu) and silver (Ag).

16. The manufacturing method of AMOLED driver circuit as claimed in claim 11, wherein the material of the passivation protection layer is silicon oxide, silicon nitride, or a combination of the two.

17. The manufacturing method of AMOLED driver circuit as claimed in claim 11, wherein the material of the transparent conductive layer is indium tin oxide (ITO).

18. The manufacturing method of AMOLED driver circuit as claimed in claim 11, wherein Step 10 uses an evaporation process or an ink-jet printing process to prepare an OLED light-emitting layer; and Step 11 uses an evaporation process to deposit an overlaying OLED cathode.
